(19) United States
(12) Patent Application Publication
(10) Pub. No.: US 2003/0090879 A1
(43) Pub. Date: May 15, 2003

(54) Dual inline memory module

(76) Inventors: Drew G. Doblar, San Jose, CA (US); Han Y. Ko, Milpitas, CA (US); Lam Dong, Union City, CA (US); Clement Fang, Cupertino, CA (US); David Jeffrey, Santa Cruz, CA (US); Tayung Wong, Fremont, CA (US); Jay Robinson, Sunnyvale, CA (US); John Carrillo, San Jose, CA (US); Nagaraj Mitty, San Jose, CA (US); Nikhil Vaidya, San Francisco, CA (US)

Correspondence Address: B. Noel Kivlin, Conley, Rose, & Tayon, P.C., P.O. Box 398, Austin, TX, 78767, US

(21) Appl. No.: 10/171,867

(22) Filed: Jun. 14, 2002

Related U.S. Application Data
(60) Provisional application No. 60/298,619, filed on Jun. 14, 2001.

(51) Int. Cl. H05K 7/00; G06F 12/00

(52) U.S. Cl. 361/728; 711/167

(57) ABSTRACT

A memory module for expanding memory of a computer. The memory module comprises a printed circuit board including a connector edge having a plurality of contact pads configured to convey data signals, power and ground to and from said printed circuit board. The power and ground contact pads alternate along said connector edge with no more than four adjacent data signal contact pads without intervening power or ground contact pads. A plurality of memory devices mounted on the printed circuit board. A clock driver is coupled to each of the plurality of memory devices and is configured to receive a differential clock signal and to produce at least one single-ended clock signal for clocking the plurality of memory devices. The clock driver includes a phase-locked loop for phase-locking the at least one single-ended clock signal.

### CROSS-REFERENCE TO RELATED APPLICATIONS

The following United States Patent applications, which are assigned to Sun Microsystems, Inc., are hereby incorporated by referenced for all purposes:

Ser. No. 09/252,768, filed Feb. 19, 1999 and entitled “Computer System Providing Low Skew Clock Signals to a Synchronous Memory Unit”; Ser. No. 09/327,058, filed Jun. 7, 1999 and entitled “A Memory Expansion Module Including Multiple Memory Banks And a Bank Control Circuit”; Ser. No. 09/347,117, filed Jul. 2, 1999 and entitled “A System and Method for Improving Multi-Bit Error Protection In Computer Memory Systems”; Ser. No. 09/442,850, filed Nov. 18, 1999 and entitled “A Memory Expansion Module with Stacked Memory Packages”; and Ser. No. 09/846,873, filed May 1, 2001 and entitled “Memory Module Having Balanced Data I/O Contacts Pads”.

### BACKGROUND OF THE INVENTION

This invention relates to computer expansion memory and more particularly to dual inline memory modules.

Many modem computer systems allow for memory expansion by way of single inline memory modules (SIMMs) and/or dual inline memory modules (DIMMs). SIMMs and DIMMs include small, compact circuit boards that are designed to mount easily into an expansion socket mounted on another circuit board, typically a computer motherboard. The circuit boards used to implement SIMMs and DIMMs include an edge connector comprising a plurality of contact pads, with contact pads typically being present on both sides of the circuit board. On SIMMs, opposing contact pads are connected together (i.e. shorted), and thus carry the same signal, while at least some of the opposing contact pads on DIMMs are not connected, thus allowing different signals to be carried. Due to this, higher signal density may be accommodated by DIMMs.

Memory elements mounted on SIMMs and DIMMs are typically Dynamic Random Access Memory (DRAM) chips or Synchronous Dynamic Random Access Memory (SDRAM) chips. STMMs and DIMMs are normally available in various total memory capacities. For example, they may be available in 64, 128 or 256 megabyte capacities. The various capacities are achieved in several ways. The first is selection of memory chips having a given address space and byte size. For example a chip may have 4M address space, i.e. four million separate addressable memory locations, with each location storing sixteen bits. Such a chip can provide storage of four million sixteen-bit words, and may be referred to as a 4M×16 chip. Since memory capacity is often rated in terms of how many eight bit words the memory stores, such a chip may be considered to have eight megabyte memory capacity. For a given size of memory chip, module capacity can be increased by using multiple chips on a board and increasing data bus width so that the data at the same addressed location in each chip can be read out to the bus simultaneously. For example, if three 4M×16 chips are used, the bus width would need to be at least forty-eight to allow all of the bits at a selected address to be read out to the bus at the same time. A module with three 4M×16 chips can be considered to have a total capacity of twelve million sixteen bit bytes, but may be called a twenty-four megabyte memory in terms of eight bit bytes.

### SUMMARY OF THE INVENTION

A memory module for expanding memory of a computer system is provided. The memory module comprises a printed circuit board including a connector edge having a plurality of contact pads configured to convey data signals, power and ground to and from said printed circuit board. The power and ground contact pads alternate along said connector edge with no more than four adjacent data signal contact pads without intervening power or ground contact pads. A plurality of memory devices mounted on the printed circuit board. A clock driver is coupled to each of the plurality of memory devices and is configured to receive a differential clock signal and to produce at least one single-ended clock signal for clocking the plurality of memory devices. The clock driver includes a phase-locked loop for phase-locking the at least one single-ended clock signal.

### BRIEF DESCRIPTION OF THE DRAWINGS

FIG. 1 is a block diagram of one embodiment of a computer system including a plurality of memory modules;

FIG. 2 is a drawing of one embodiment of a memory module;

FIG. 3 is a drawing of one embodiment of the opposing side of the memory module of FIG. 2;

FIG. 4 is a pad assignment table for one embodiment of a memory module;

FIG. 5 is a block diagram illustrating an embodiment of a computer system having a CPU, a memory controller, a CPU bus, and a plurality of memory modules;

FIG. 6 is a mechanical drawing of one embodiment of a memory module;

FIG. 7A is a block diagram illustrating the electrical connections associated with the top side of an embodiment of the memory module;

FIG. 7B is a block diagram illustrating the electrical connections associated with the bottom side of an embodiment of the memory module;

FIG. 8 is a functional block diagram of one embodiment of the memory module;

FIG. 9 is a pin diagram of one embodiment of a stacked memory package;

FIG. 10 is a block diagram of the internal organization of one embodiment of a stacked memory package;

FIG. 11 is a drawing of one embodiment the memory module illustrating the electrical interconnections associated with error correction functions;

FIG. 12 is a table illustrating exemplary entries within the storage unit correlating connector pins to integrated circuit pins.

FIG. 13 is a block diagram illustrating the electrical connections associated with an embodiment of the memory module;

FIG. 14 is a drawing illustrating an embodiment of a bank control circuit;

FIG. 15 is a schematic of a bank control circuit;

FIG. 16 provides a list of the assignments for the 232 pin edge connector of the NG DIMMS;

FIG. 17 is a block diagram for 8/16/32M×144 capacity NG DIMMs;

FIG. 18 is a block diagram for 64/128M×144 capacity NG DIMMs;

FIG. 19 is a dimensioned drawing of a printed circuit board on which a memory module is assembled;

FIGS. 19A through 19I are dimensioned drawings showing details of the printed circuit board of FIG. 19;

FIG. 20 provides additional dimensioned details for the printed circuit board of FIG. 18;

FIG. 21 is a table of electrical absolute maximum ratings for NG DIMMs;

FIG. 22 is a table of recommended operating conditions for NG DIMMs;

FIG. 23 is a table of DC characteristics for NG DIMMs;

FIG. 24 is a table of capacitance characteristics for NG DIMMs;

FIG. 25 is a table of AC characteristics for NG DIMMs;

FIG. 26 is a timing diagram for a read transaction for NG DIMMs;

FIG. 27 is a timing diagram for a write transaction for NG DIMMs;

FIG. 28 is a timing diagram for a mode register set cycle for NG DIMMs; and,

FIG. 29 is a timing diagram for a self-refresh entry and exit cycle for NG DIMMs.

While the invention is susceptible to various modifications and alternative forms, specific embodiments thereof are shown by way of example in the drawings and will herein be described in detail. It should be understood, however, that the drawings and detailed description thereto are not intended to limit the invention to the particular form disclosed, but on the contrary, the intention is to cover all modifications, equivalents and alternatives falling within the spirit and scope of the invention as defined by the appended claims.

### Notation and Nomenclature

Certain terms are used throughout the following description and claims to refer to particular system components. As one skilled in the art will appreciate, computer companies may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . ”. Also, the term “couple” or “couples” is intended to mean either an indirect or direct electrical connection. Thus, if a first device couples to a second device, that connection may be through a direct electrical connection, or through an indirect electrical connection via other devices and connections.

### Detailed Description of Preferred Embodiments

### DIMM with Balanced Data I/O Contacts

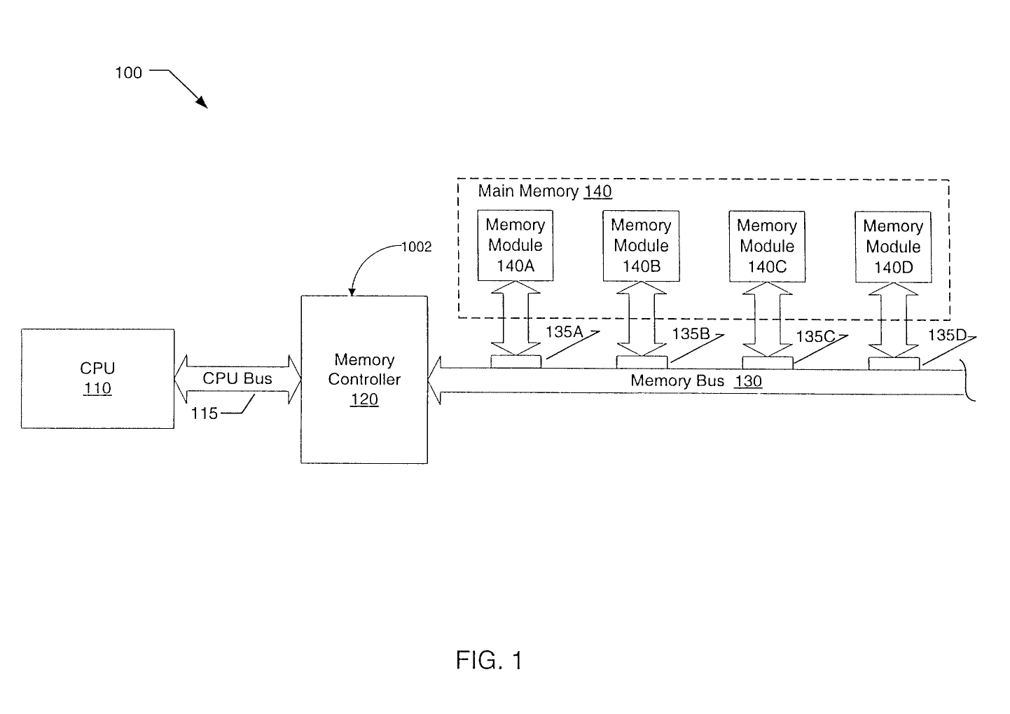

Turning now to FIG. 1, a block diagram of one embodiment of a computer system including a plurality of memory modules is shown. Computer system 100 includes a central processing unit (CPU) 110 coupled to a memory controller 120 through a CPU bus 115. Computer system 100 further includes a main memory 140 coupled to memory controller 120 through a memory bus 130. Memory bus 130 includes connector sockets 135A-135D.

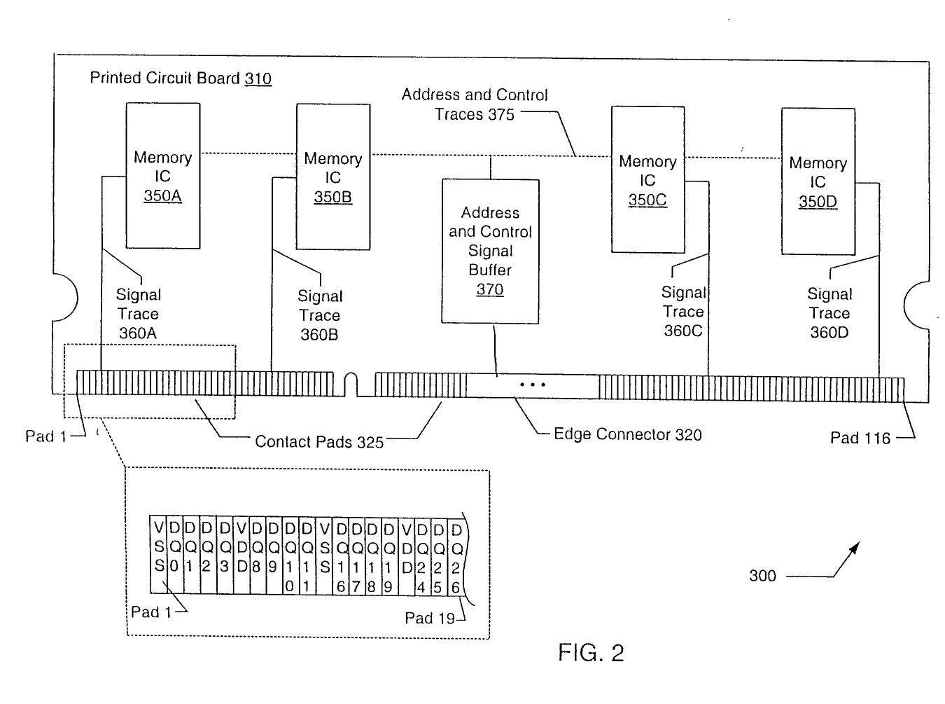

In the illustrated embodiment, main memory 140 is implemented using memory modules 140A-140D which are connected to memory bus 130 through connector sockets 135A-135D. As will be described further below in conjunction with FIG. 2, an edge connector associated with each of the memory modules may be mated with each one of the connector sockets. When inserted into a connector socket 135, a memory module such as memory module 140A may provide computer system 100 with a main memory. To expand memory, additional memory modules may be inserted into unoccupied connector sockets. Although main memory 140 is shown with four memory modules, it is noted that main memory 140 may be implemented using any suitable number of memory modules depending on the particular system implementation.

Referring to FIG. 2, a drawing of one embodiment of a memory module is shown. Memory module 300 includes memory integrated circuits (ICs) or memory chips 350A-350D which may be mounted to a printed circuit board (PCB) 310 using a variety of techniques such as surface mounting, for example. PCB 310 is a circuit board including various signal traces 360A-360D that couple memory ICs 350A-350D to an edge connector 320 containing contact pads 325. Memory module 300 also includes one or more address and control signal buffer IC 370. It is noted that in other embodiments, memory module 300 may not include address and control signal buffers. It is further noted that other embodiments may include other integrated circuit chips that may include additional control functionality as well as memory module configuration information.

Signal traces 360A-360D convey signals such as data, address and control information as well as power and ground between edge connector 320 and memory ICs 350A-350D. Contact pads 325 make physical contact with various types of contacts on a mating connector socket similar to connector socket 135A in FIG. 1. In one embodiment, PCB 310 of FIG. 2 is a multi-layered circuit board which includes signal traces 360A-360D on some layers and power and ground planes on other layers.

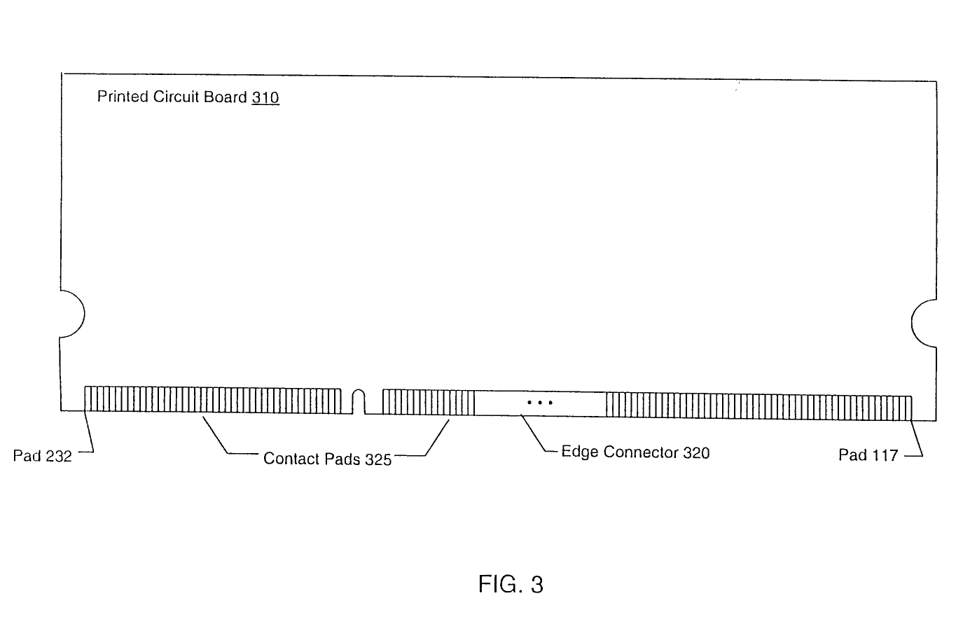

In the illustrated embodiment, contact pads numbered 1 through 116 are shown on one side of PCB 310. Edge connector 320 contains 232 contact pads. FIG. 3 illustrates the numbering of contact pads 117 through 232 on the opposite side of PCB 310. Contact pad number 117 is opposite contact pad number 1 and contact pad 232 is opposite contact pad 116. Contact pads 325 are sequentially numbered and distributed along the length of edge connector 320 on each side of PCB 310. Contact pads 325 allow various address, data and control signals in addition to power and ground, to pass between PCB 310 and a memory bus such as memory bus 130 of FIG. 1. It is noted that although edge connector 320 is shown with 232 contact pads, it is contemplated that in other embodiments edge connector 320 may have other numbers of contact pads.

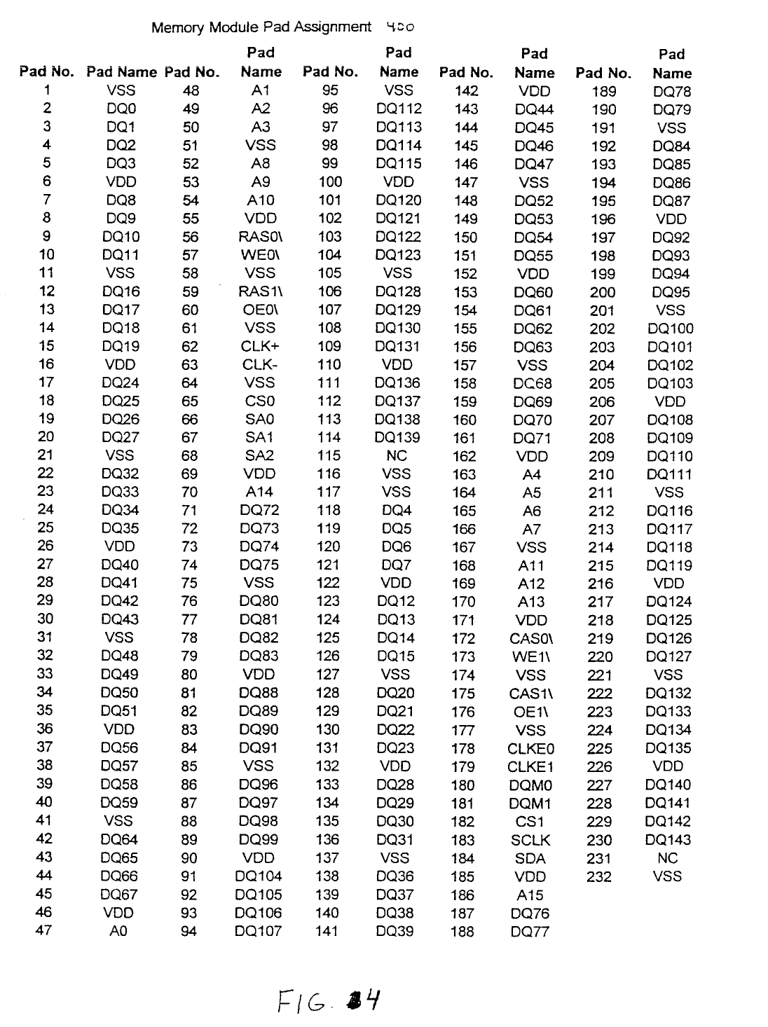

As will be described in greater detail below in conjunction with the description of FIG. 4, the exploded view of FIG. 2 illustrates a small portion of edge connector 320 on the front side of PCB 310.

Turning now to FIG. 4, a pad assignment table for one embodiment of a memory module is shown. Memory module pad assignment table 400 is an exemplary diagram illustrating the numbering of the contact pads and the signals assigned to the corresponding pad numbers associated with edge connector 320 of FIG. 2. Pad assignment table 400 includes multiple rows and columns. The columns are labeled Pad Number and Pad Name. Therefore, each pad number has a corresponding pad name associated with it. For example, Pad number 1 is referenced as VSS. Pad number 2 is referenced DQ0 and so forth. In this particular embodiment, the ground pads are referenced VSS and the power pads are referenced VDD. Further, the data signal pad names are DQ0-DQ143.

Referring collectively to FIG. 2 through FIG. 4, power and ground contact pads are distributed along the length of edge connector 320 in an alternating pattern forming adjacent VSS-VDD contact pad pairs. To illustrate, refer back to the exploded view of edge connector 320 in FIG. 2. Contact pad 1 is a ground contact pad while contact pad 6 is a power contact pad. Further, contact pad 11 is also a ground contact pad and contact pad 16 is a power contact pad. This alternating pattern may continue along the entirety of edge connector 320. As used herein, an adjacent power and ground contact pad pair refers to any particular pair of power and ground contact pads that have no other power or ground contact pads between the particular pair of power and ground contact pads. For example, contact pad 6 and contact pad 1 are an adjacent power and ground contact pad pair. Additionally, contact pad 6 and contact pad 11 are an adjacent power and ground contact pad pair. In contrast, contact pad 1 and contact pad 16 are not an adjacent power and ground contact pad pair because contact pad 11 is an intervening ground contact pad.

Referring again to pad assignment table 400, it is noted that that there are no more than four data signal contact pads between any adjacent VSS-VDD contact pad pair (e.g., pads DQ0-DQ3 are between pads 1 and 6). Although in some embodiments, there may be less than four data signal contact pads between any adjacent VSS-VDD contact pad pair.

In the illustrated embodiment, there are more than four contact pads between some adjacent VSS-VDD contact pad pairs, but there are not more than four data signal contact pads. For example, between the VSS-VDD contact pad pair formed by pads 110 and 116, there are five contact pads. However, one pad (pad 115) is designated as a no-connect and thus referenced as NC. In another example, there are multiple non-data signal contact pads between the VSS-VDD contact pad pair formed by pads 177 and 185, but that there are still no more than four data signal between any adjacent VSS-VDD contact pad pair.

Evenly distributing the data signal contact pads between adjacent power and ground contact pad pairs may improve data signal integrity by reducing the signal return path length associated with a particular data signal. Further, by separating the power and ground contact pads power to ground short circuits may be minimized.

### DIMM with Stacked Memory Packages

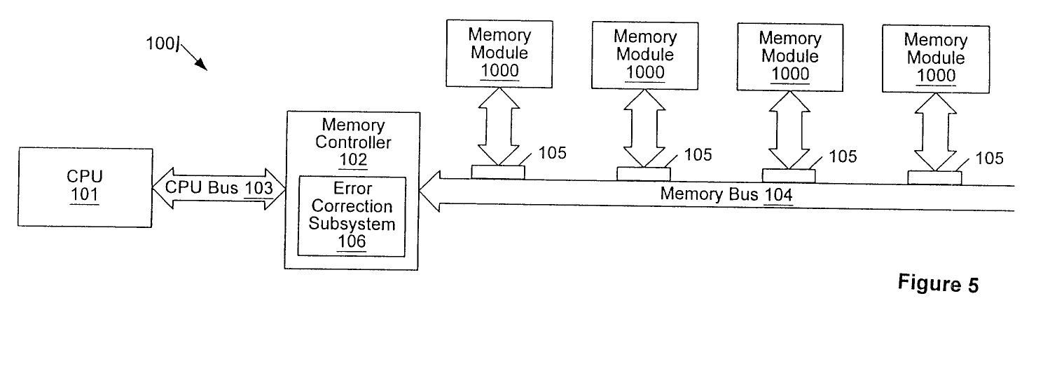

With reference now to FIG. 5, another embodiment of a computer system 1001 including a plurality of memory modules 1000, as will be described below, is shown. The computer system includes a CPU 101, coupled to a memory controller 102 through a CPU bus 103. Memory controller 102 is configured to control communications and data transfers between CPU 101 and memory modules 1000.

Memory controller 102 is coupled to each of the memory modules 1000 through a memory bus 104. Memory bus 104 includes a plurality of signal lines, each of which is associated with a single data bit position. The width of memory bus 104 may be any number of bits; typical bus widths include 16 bits, 32 bits, 64 bits, and 128 bits. Some embodiments of memory bus 104 may include extra signal lines for bits that may be used by error correction circuitry. The bits conveyed by the extra signal lines are typically referred to as check bits. For example, one embodiment of a memory bus may be configured to convey 128 data bits and 16 check bits, for a total bus width of 144 bits. Error detection and correction is performed by error correction subsystem 106, located within memory controller 102.

In the embodiment shown in FIG. 5, the memory modules are provided to expand main memory of computer system 1001, and are electrically coupled to memory bus 104 through a set of expansion sockets 105. An expansion socket 105 of this embodiment is configured to receive an edge connector of a printed circuit board of a memory module 1000.

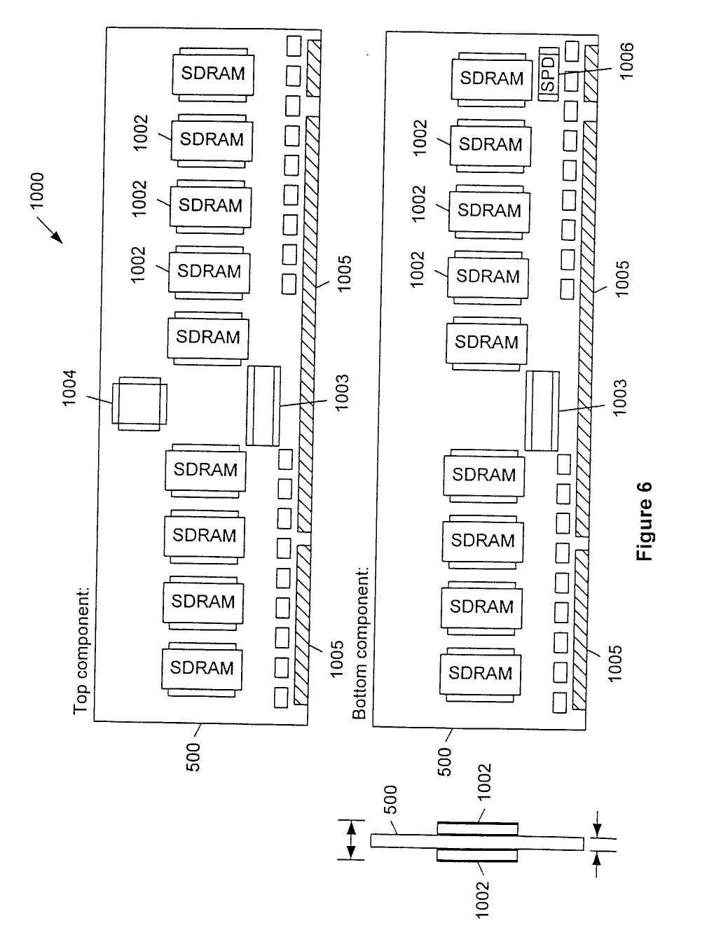

501 Moving on to FIG. 6, a mechanical drawing of one embodiment of the memory module is shown. Memory module 1000 includes a plurality of stacked memory packages 1002 mounted upon both sides of a printed circuit board 500. Memory module 1000 also includes two line driver chips 1003, one mounted on each side of the printed circuit board. In this embodiment, clock driver chip 1004 is mounted on the top side of printed circuit board 500, while a storage unit 1006 is mounted on the bottom side. Edge connector 1005 provides electrical contact between the various components of the module and the computer system 1001 of FIG. 1. In the embodiment shown, edge connector 1005 includes 232 electrical contacts. Furthermore, a majority of opposing electrical contacts of edge connector 1005 are not electrically connected, making this module a DIMM (dual inline memory module).

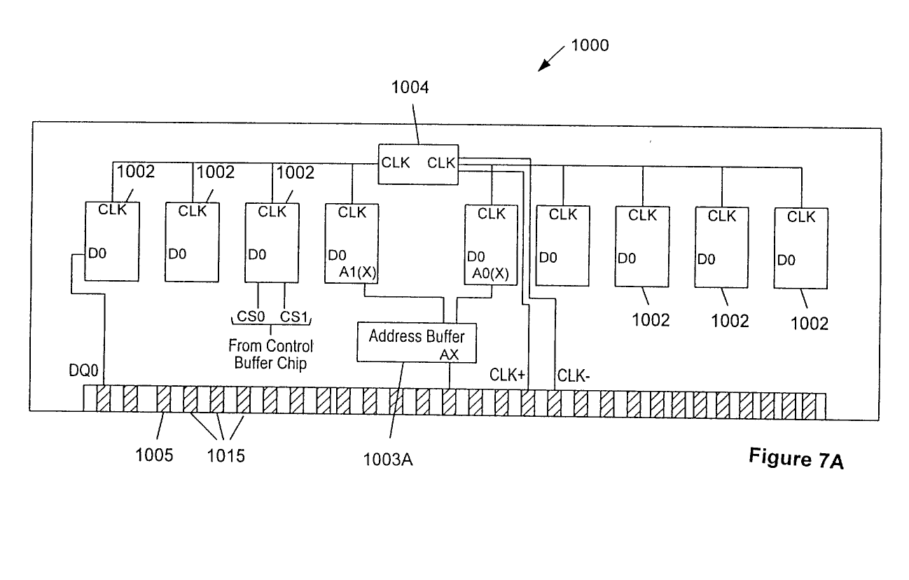

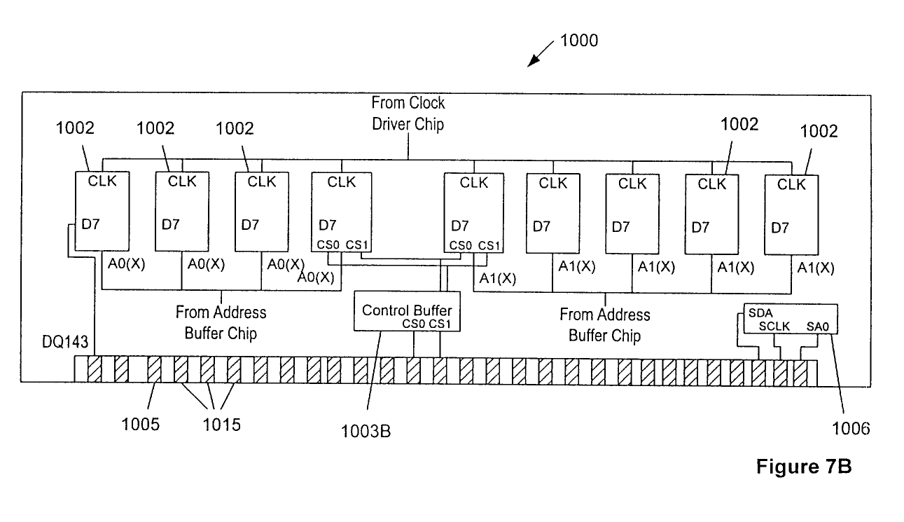

FIGS. 7A and 7B are block diagrams illustrating the electrical connections associated with the top and bottom side, respectively, of one embodiment of the memory module. Memory module 1000 includes a plurality of stacked memory packages 1002 mounted upon each side. Memory module 1000 also includes edge connector 1005 for electrically coupling memory module 1000 to the memory bus 104 of FIG. 1. Edge connector 1005 includes a plurality of electrical contacts 1015 for conveying electrical signals between memory module 1000 and the memory bus. As in FIG. 6, a majority of opposing contacts in the embodiment shown are not electrically connected, making the module a DIMM.

On each side of memory module 1000 is mounted a line driver (or buffer) chip 1003. Line driver chip 1003-A in FIG. 3A serves as an address buffer (for address signals), while line driver chip 1003-B in FIG. 3B serves as a control buffer (for control signals). Line driver chip 1003-A is configured to receive address signals from a memory bus of a computer system, via electrical contact pads 1015 and interconnecting signal lines. In the embodiment shown, each address signal is split into two separate signals. Those address signals labeled A0(X) are driven to a first memory bank, while those labeled A1(X) are driven to a second memory bank. Line driver chip 1003-B is configured to receive various control signals from a memory bus. These control signals include chip select signals; CS0 and CS1 as shown. Other control signals (not shown) include row address strobe (RAS), column address strobe (CAS), clock enable (CKE), and write enable (WE) as described in Table 1 above.

The top side of the module also includes clock driver chip 1004. Clock driver chip 1004 is configured to receive clock signals from a computer system, and to drive these signals to the memory chips of the stacked memory packages 1002. In the embodiment shown, clock driver chip 1004 actually receives two differential PECL (pseudo emitter coupled logic) level signals, designated here as CLK+ and CLK−. These differential signals are used as inputs to a phase-locked loop (PLL) circuit within the clock driver chip. The output of the PLL is a singular clock signal, which is driven to each of the memory chips within the stacked memory packages 1002. Other embodiments configured to receive a singular clock signal (rather than multiple differential clock signals) are possible and contemplated.

A storage unit 1006 is mounted upon the bottom side of the module. In the embodiment shown, storage unit 1006 is a serial EEPROM (electrically erasable read-only memory). Other embodiments may use a flash memory or other type of device to implement storage unit 1006. In the embodiment shown, storage unit 1006 performs several functions. One of these functions is module identification, as storage unit 1006 may, in one embodiment, be configured to store a unique serial number for memory module 1000. This serial number may be read by a computer system into which the memory module is inserted. Using the unique serial number, the module history may be traced from its time of manufacture, including any failure information. In addition the storage unit 1006 may store other module identification information such as total storage capacity and whether the module uses stacked chips.

Another function of storage unit 1006 is the storage of error correction information. In particular, the storage unit 1006 of the embodiment shown is configured to store information correlating pins of the connector edge to individual pins of stacked memory packages 1002. Using this information, an error detected by an error correction subsystem may be quickly traced to a specific pin of a specific stacked memory package 1002.

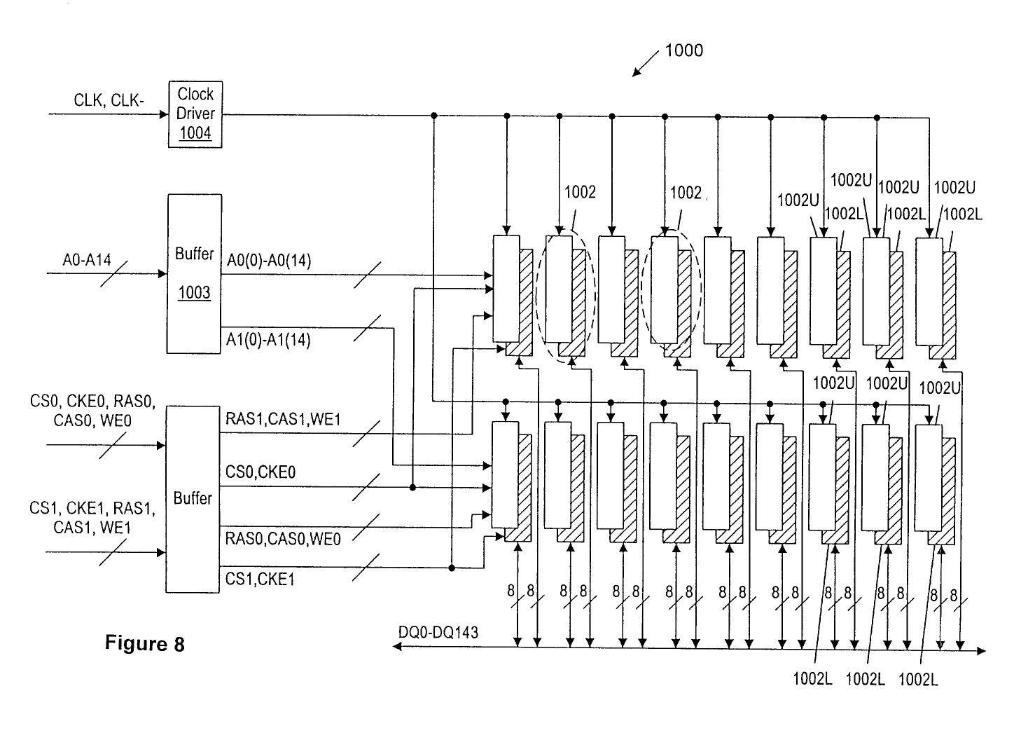

Turning now to FIG. 8, a functional block diagram of one embodiment of the memory module is shown. Memory module 1000 includes a plurality of memory die 1002U and 1002L, wherein each pair of die is part of a stacked memory package 1002 of FIGS. 6 and 7. Typically, memory die 1002U and 1002L will be dynamic random access memory (DRAM) chips or synchronous dynamic random access memory (SDRAM) chips. In the embodiment shown, a first bank and a second bank of memory are present. The first bank of memory includes the shown plurality of memory die 1002U, while the second bank includes the shown plurality of memory chips 1002L. Each memory die has a data width of 8 bits, and is coupled to a data bus of 144 bits.

Two buffers, or line driver chips 1003 are used to drive address and control signals to the memory die 1002U and 1002L. One line driver chip 1003 is used exclusively for address signals. Each address signal received by the line driver chip 1003 is duplicated twice and driven to a stacked memory package 1002. A second line driver chip 1003 is used to drive control signals to the memory die 1002U and 1002L within each stacked memory package in order to control the individual banks of memory. Each stacked memory package 1002 is configured to receive a RAS signal (RAS0 or RAS1), a CAS signal (CAS0 or CAS1), and a WE signal (WE0 or WE1). In addition, each stacked memory package 1002 is configured to receive control signals CS0, CS1, CKE0, and CKE1.

Also shown in FIG. 8 is clock driver chip 1004, which is configured to receive two differential PECL clock signals, and drive a singular clock signal to each of the memory chips, as explained above with reference to FIG. 7A.

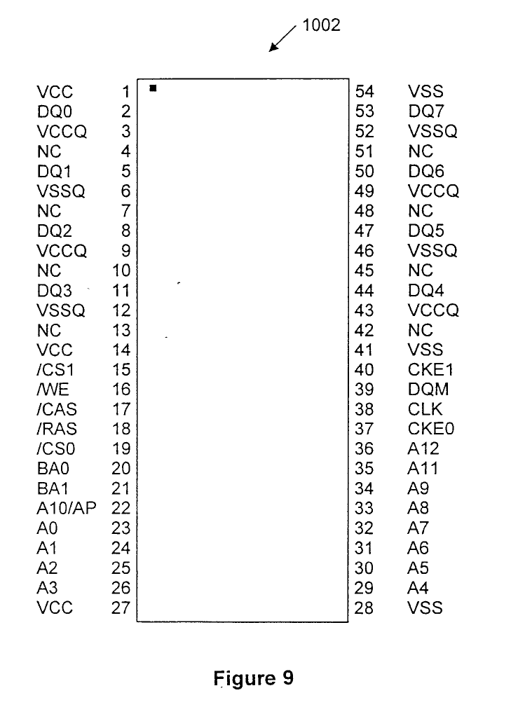

FIG. 9 is a pin diagram of one embodiment of a stacked memory package 1002. In the embodiment shown in FIG. 8, stacked memory package 1002 includes two memory die. Each stacked memory package is configured to receive 8 data signals (DQ0-DQ7), 15 address signals (A0-A12 and BA0-BA1), and control signals CS0, CS1, CKE0, CKE1, RAS, CAS, and WE. Address signals BA0 and BA1 correspond to address signals A13 and A14 as shown in FIG. 8. In general, a limitation of two memory die per stacked memory package is placed upon the various embodiments of the memory module, due to considerations for power consumption and thermal output of the module. Stacked packages with only two memory die may consume less power and generate less heat than those containing three or more memory die, while still allowing additional memory capacity without the need for additional circuit area relative to memory packages having a single memory die.

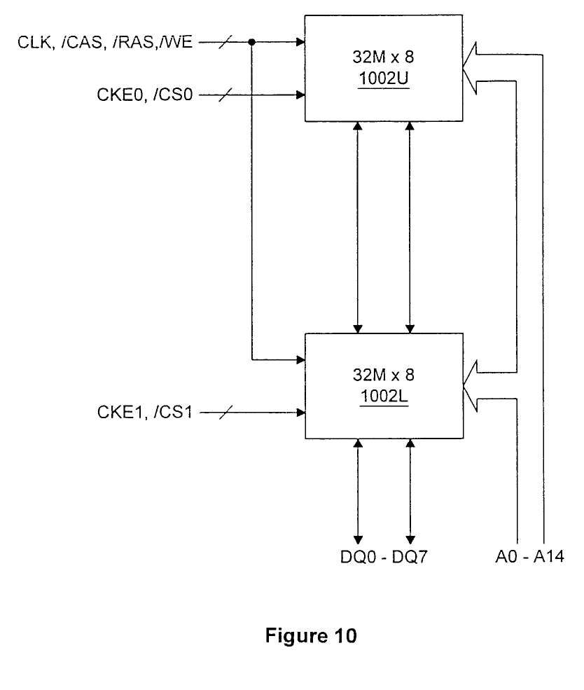

FIG. 10 is a block diagram of the internal organization of one embodiment of a stacked memory package. The embodiment shown consists of memory die 1002U and 1002L. Address signals A0-A14 are coupled to both memory die, as are control signals CAS, RAS, and WE, and data signals DQ0-DQ7. A clock signal, CLK, is also coupled to both memory die. Control signals CKE0 and CS0 are coupled to memory die 1002U, and are asserted during read and write operations to this memory die. Likewise, control signals CKE1 and CS1 are coupled to memory die 1002L. Memory die 1002U and 1002L are part of a first and a second memory bank, respectively. The memory die in this embodiment are 32M×8 (i.e. 32 megabytes) each, resulting in a stacked memory package with a capacity of 64 megabytes. Using a total of 18 stacked memory packages of this capacity results in a module capacity of one gigabyte.

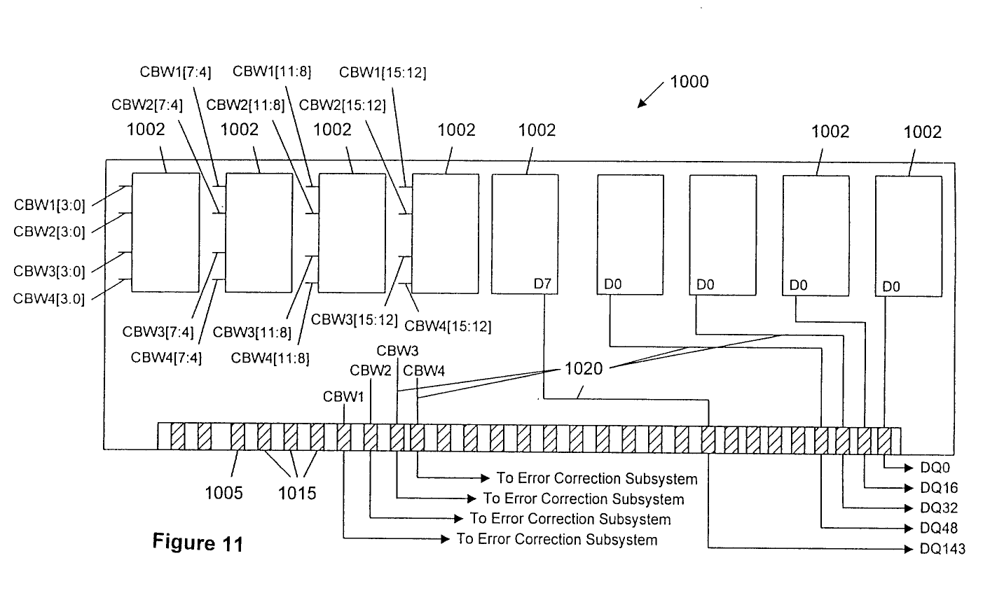

FIG. 11 is a drawing of one embodiment the memory module illustrating the electrical interconnections associated with error correction functions. Memory module 1000 includes a printed circuit board upon which stacked memory packages 1002 are mounted. Each of these packages has a data width of 8 bits, and includes two memory chips (1002U and 1002L from FIGS. 8 and 10). Depending on the organization of memory module 1000, some of these memory die may be used to store error correction check bits, while others may be used to store data bits. Memory module 1000 also includes an edge connector 1005, with a plurality of electrical contact pads 1015. A plurality of signal lines 1020 couples the electrical contact pads 1015 to the stacked memory packages 1002. Data signals are conveyed along signal lines 1020 between the stacked memory packages 1002 and electrical contact pads 1015. Data pin D0 of each stacked memory package 1002 is shown coupled to electrical contact pads 1015 by signal lines 1020, with the respective position of the bit in the data word (i.e. DQ0, DQ16, etc.) shown. The most significant bit of the data, DQ143, is coupled to pin D7 of a stacked memory package 1002. In this embodiment, 16 check bits are used to protect each data block of 128 bits, with each check word associated with one data block only.

As previously stated, some memory die of the stacked memory packages 1002 may be used exclusively to store check bits in this embodiment. Each of these memory die may store four check bits of each check word. In the embodiment shown, each check word is 16 bits, and protects a data block of 128 bits. These check bits are accessed through a plurality of pins designated CBWX[y:z]. For example, CBW1[3:0] shown in the drawing represents four pins of a stacked memory package 1002 through which check bits 0 through 3 of check word #1 are accessed. Similarly, CBW2[7:4] represents those pins through which check bits 4 through 7 of check word #2 are accessed. Each of these pins is connected to a respective signal line. Representative signal lines are shown in the drawing as CBW1 through CBW4. In general, these signal lines are routed on the printed circuit board in such a manner that physically adjacent memory cells within each memory die store check bits corresponding to different check words.

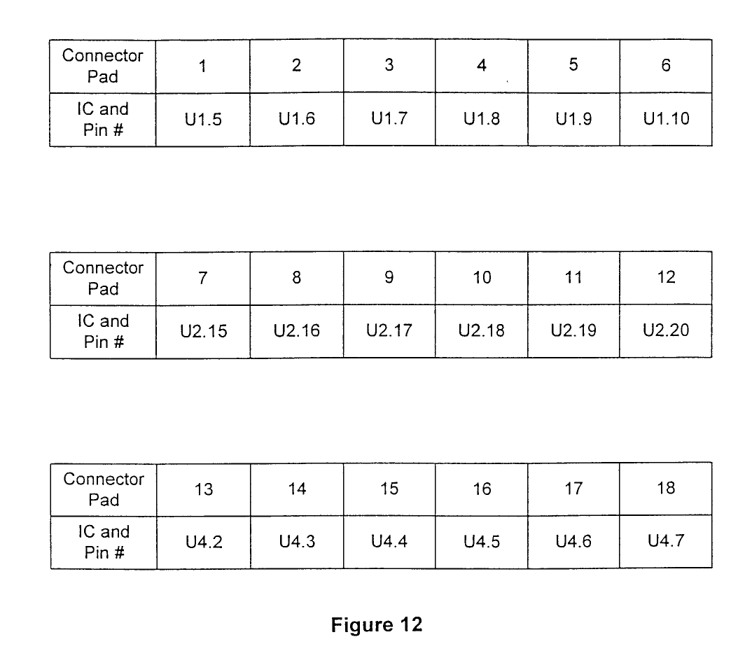

FIG. 12 is a table illustrating exemplary entries within the storage unit correlating connector pins to integrated circuit pins. In the table shown, each connector pad of an edge connector (such as edge connector 1005 of FIGS. 7A and 7B) is associated with a pin of an integrated circuit package (such as the stacked memory packages 1002 of FIGS. 7A and 7B). For example, connector pad #1 is associated with integrated circuit U1, pin 5 (U1.5). Similarly, connector pad #5 is associated with integrated circuit U1, pin 9. Most, if not all, connector pads may be associated with at least one pin of one integrated circuit. In many cases, certain connector pads may be associated with a plurality of integrated circuit pins. Such connector pads may include those that carry address signals and enable signals (e.g. chip enable and write enable signals).

### DIMM with Bank Select Circuit

In the previously described embodiments, the memory modules 140 and 1000 may include memory chips 350 or 1002 organized into banks. All banks on a module share the same data bus. Therefore, only one bank may be active, i.e. performing a read or write operation, at any given time. As a result, a bank selection arrangement is needed. In the above described embodiments, the bank selection is made by memory controller 102 or 120, by asserting control lines to only the one selected bank at any given time. In another embodiment, the bank control circuit is placed on the printed circuit board 310 or 500.

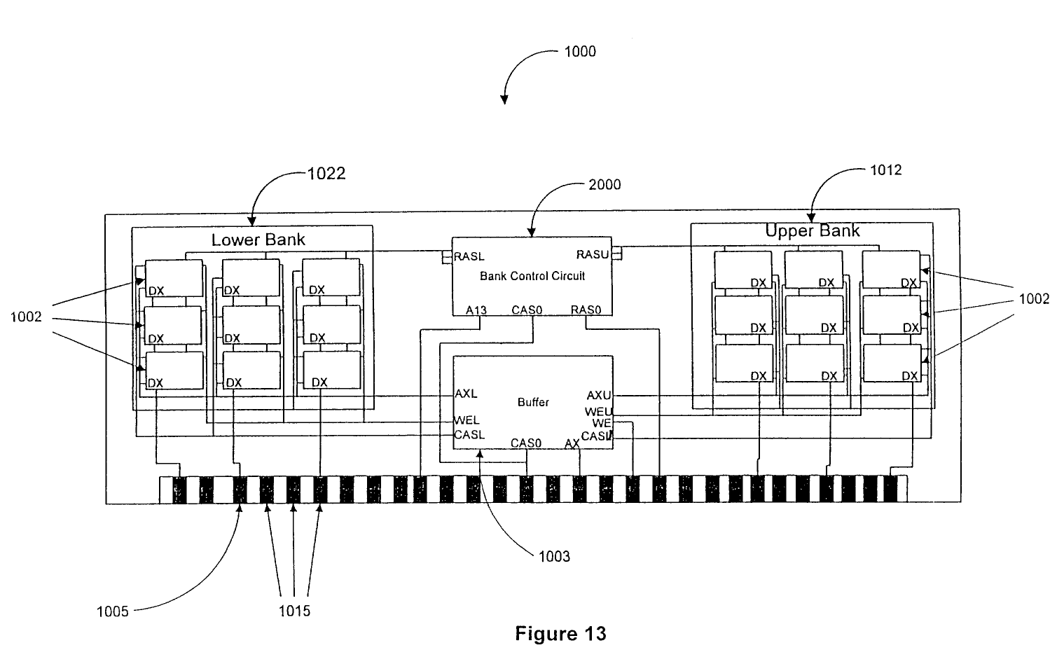

FIG. 13 is a block diagram illustrating the electrical connections associated with an embodiment of a memory module 1000 having a bank select circuit. Those features of this embodiment which correspond to the above described embodiments are given the same reference numbers. Memory module 1000 includes an edge connector 1005, a lower memory bank 1022, and upper memory bank 1012, a bank control circuit 2000 and a buffer 1003. Each memory bank includes of a plurality of memory chips 1002. The edge connector 1005 includes a plurality of electrical contact pads 1015 which convey signals between the memory module and the system memory bus. Edge connector 1005 is adapted for mounting in a socket within a computer system. Buffer 1003 receives signals WE (write enable), CAS0 (Column Address Strobe 0), and a plurality of address signals, shown as AX. Buffer circuit 1003 drives a plurality of address signals AXL and AXU, which are conveyed to the lower memory bank 1022 and upper memory bank 1012, respectively. WEL and WEU are write enable signals driven by buffer 1003 to a lower memory bank 1022 and an upper memory bank 1012, respectively. CASL and CASU are CAS signals driven by buffer 1003 to the lower memory bank 1022 and upper memory bank 1012, respectively. The bank control circuit 2000 is configured to receive an address signal A13 for selecting the upper and lower bank. Address signal A13, in this embodiment, is the most significant address bit of an address bus that is 14 bits wide. Bank control circuit 2000 is also configured to receive a CAS0 signal and a RAS0 (Row Address Strobe 0) signal. A plurality of data lines, represented in the drawing as DX, convey data signals between the memory chips 1002 and system memory bus 104 of FIG. 1. In this particular embodiment, the data path is 144 bits wide.

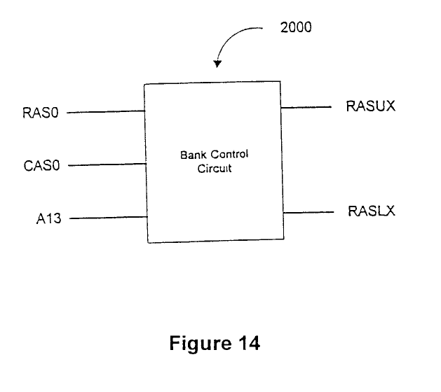

One embodiment of bank control circuit 2000 is shown in FIG. 14. In this embodiment, bank control circuit 2000 receives input signals RAS0, CAS0, and address signal A13. Bank control circuit 2000 drives a plurality of RASLX and RASUX signals to the lower and upper memory banks, respectively. Depending on the combination of inputs received by bank control circuit 2000, either the RASUX or RASLX signal groups can be asserted exclusively for memory access operations. Another combination of inputs will assert all RASUX and RASLX signals in order to perform a CBR (Columns before Rows) refresh cycle.

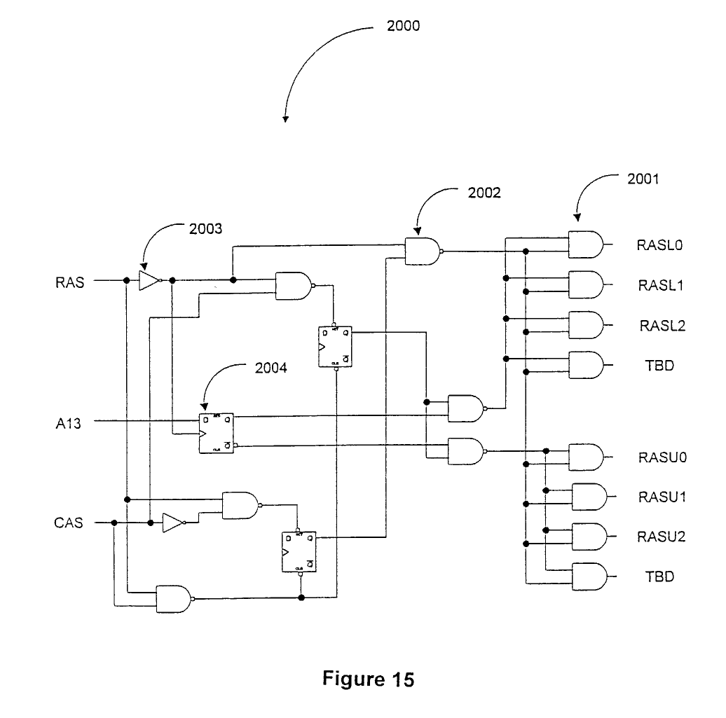

Turning now to FIG. 15, a schematic of one embodiment of the bank control circuit 2000 is shown. This particular embodiment of bank control circuit 2000 is a programmable logic device (PLD). In this embodiment, bank control circuit 2000 comprises a plurality of AND gates 2001, NAND gates 2002, inverters 2003, and flip-flops 2004 (D-type flip-flops in this embodiment). Bank control circuit 2000 drives multiple RAS signals for each memory bank in order to provide sufficient signal drive strength to each of the memory chips.

While FIG. 13 is intended to be a block diagram, and not a physical layout, of a memory module 1000, it helps to illustrate alternative arrangements of memory chips 1002. FIG. 13 shows an embodiment where the memory chips are divided into two groups, or banks, of memory on one module. In this embodiment, each bank comprises nine chips. For example, each chip may provide storage for 16 data bits at each of 8, 16 or 32 million addresses. In this case of chips with 16 bits of storage at each address, each chip 1002 would be in a physically separate package mounted on a printed circuit board forming the module 1000. One half of the packages would normally be mounted on each side of the board. However, as discussed with reference to FIG. 8, each physical package may contain two separate chips. Each such stacked chip may have 32 million addresses storing eight bits of data at each location. In this case of eight bits of storage at each address, a bank may comprise the combination of one chip in each of the physical packages mounted on the printed circuit board.

### Next Generation DIMM Modules

The following description provides details of preferred embodiments of DIMM modules which include many of the features of the above described embodiments. They are referred to as “Next Generation DIMM” modules or “NG DIMMs” because they are believed to include the best combination of features in view of currently available components and current requirements for memory modules needed in computer systems.

The NG DIMM is a 8 or 16 or 32 or 64 or 128M×144 DIMM module designed for 3.3V LVTTL SDRAM chips. The module is organized as one or two banks of 4M×144, 8M×144, 16M×144, 32M×144, or 64M×144 with independent controls for the two physical banks. These NG DIMMs therefore have nominal memory capacities of 128, 256, 512, 1024 and 2048 MB (megabyte) respectively, based on eight bit bytes and having two banks of chips on each module. The modules may also be populated with a single bank of chips if desired. Since each bank is provided with independent controls, a single bank will function properly whether or not the other bank is populated with chips. With the buffering of signals provided herein, the access time for a bank of chips is not affected by the presence of a second bank on a given module.

The NG DIMMs may include the following components and have the following features.

18 4/8/16M×16 SDRAM in TSOP packages or 18 64/128M×8(2*32/64M×8) “stacked” SDRAMs

Two 18-to-36-bit CMOS line drivers in an 80-pin 0.4 mm pitch TVSOP package

One 1-to-9 PLL clock driver in a 32-lead TQFP package

A SPD serial EEPROM in a 8-pin TSOP package.

8/16/32/64/128M×144 (128/256/512/1024/2048 MB ) capacity

232-pin connector

1.27 mm lead pitch

Single 3.3V+/−10% supply

CAS latency=2 at 75 MHz

4K refresh for 64 Mb SDRAM and 8K refresh for 256 Mb SDRAM

All inputs are buffered on the module including differential PECL clock.

Maximum loading of single-ended LVTTL clock outputs is 2 SDRAM.

Serial Presence Detect(SPD) serial EEPROM for module identification

SDRAM 4M×16 is in 54-pin 400 mil wide TSOP package with 0.8 mm pitch.

SDRAM 8M×16 is in 54-pin 400 mil wide TSOP package with 0.8 mm pitch.

SDRAM 16M×16 is in 54-pin 400 mil wide TSOP package with 0.8 mm pitch.

SDRAM 64M×8 is stacked 2*32M×8 in a stacked package.

SDRAM 128M×8 is stacked 2*64M×8 in a stacked package.

The signals used in the NG DIMMs are described in Table 1.

TABLE 1

| Pin Name | Description |
|---|---|
| DQ0 to DQ143 | Data I/O |
| A0 to A15 | Address Inputs |
| CAS0\, CAS1\ | Column Address Strobe for each |
| | bank |
| RAS0\, RAS1\ | Row Address Strobe for each bank. |
| WE0\, WE1\ | Write Enable for each bank |
| CLK+, CLK− | PECL Clock input to clock driver |
| CLKE0, CLKE1 | Clock enable for each bank |
| CS0\, CS1\ | Command strobe for each bank |
| DQM0, DQM1 | Data mask for each bank |
| MR | PLL reset for clock driver |
| PLL_VDD | PLL power for clock driver |
| ByPass | PLL Bypass control |
| VCO_Sel | VCO Divider |
| SCLK | Serial Clock for SPD EEPROM |
| SDA | Serial Data I/O for SPD |
| SA0 to SA2 | SPD EEPROM Address |
| WP | SPD Write Protect |
| VCC | +3.3 V +/− 5% |
| VSS | Ground |

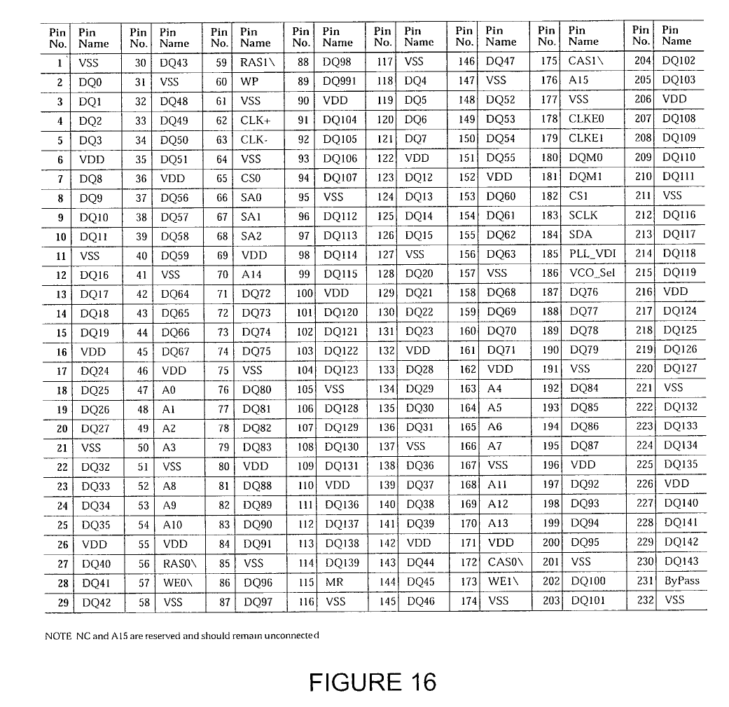

FIG. 16 provides a list of the assignments for the 232 pin edge connector of the NG DIMMS.

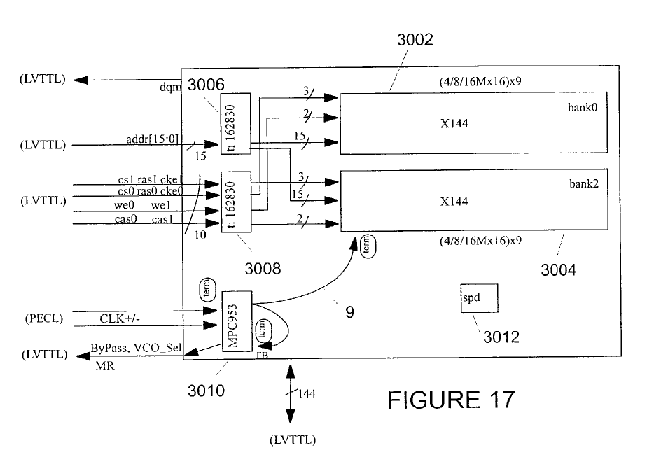

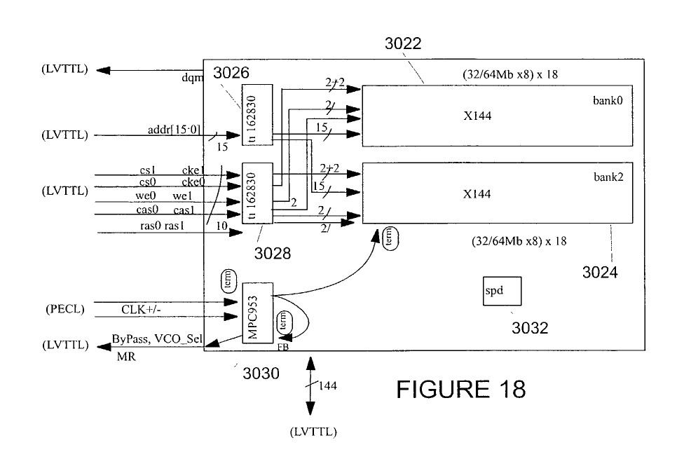

FIGS. 17 and 18 provide block diagrams for 8/16/32M×144 and 64/128M×144 capacity NG DIMMs respectively. Two SN74ALVCH162830 CMOS drivers in 80-pin TVSOP packages with 0.4 mm lead pitch are used to buffer the address and control signals to two physical banks of 9 or 18(for stacked packages) SDRAMs each. The buffers arc 18 input to 36 output LVTTL to LVTTL drivers with one input driving two outputs, each with 9 or 18(for stacked packages) SDRAM loads.

In FIG. 17, a NG DIMM has two banks 3002, 3004 of memory chips. As indicated, each bank comprises nine chips, each having 4, 8 or 16 million addressable memory locations, with each location storing sixteen bits. Each chip is in a separate package mounted on a printed circuit board. Nine packages are mounted on each side of the board. Two buffers 3006, 3008 receive address and control signals, replicate each address and control signal and drive the address and control signals to inputs of the banks 3002, 3004.

Buffer 3006 receives address signals, addr[15:0], at its inputs and provides two copies of fifteen of the address signals at its outputs. One set of outputs is coupled to address inputs of each of the memory banks 3002, 3004.

Buffer 3008 receives a total of ten control signals at its inputs, comprising two sets of five control signals, one set intended for each of banks 3002, 3004. The same set of ten control signals is replicated at ten outputs of buffer 3008 which drive the signals to the memory banks 3002, 3004 as indicated. Note that the buffer used in this embodiment actually provides two outputs for each input, so that the ten input signals appear on two sets of ten outputs. But since each control signal is coupled to only one bank of chips, the duplicate outputs are not used. In this embodiment, bank selection is made by the system memory controller which generates complete sets of control signals for each bank. A bank control circuit is therefore not needed on these NG DIMMs.

The FIG. 17 module also includes a clock driver 3010 which receives a differential clock signal from the computer system and produces a single ended clock signal for driving clock inputs of banks 3002, 3004. This clock driver operates like the clock driver 1004 described above with reference to FIG. 7. The clock driver 3010 provides nine clock outputs, each of which drives two of the chips comprising banks 3002, 3004. A Serial Presence Detect (SPD) serial EEPROM 3012 is also included for module identification as discussed above with reference to FIG. 6.

The FIG. 18 embodiment is very similar to the FIG. 17 embodiment. The main difference is that memory banks 3022, 3024 each comprise 18 memory chips and the chips are packaged in stacked packages, each of which contains two chips. These chips are organized as shown in FIG. 8 so that each bank is formed from one chip in each package. Since there are 18 chips in each bank, buffers 3026, 3028 have twice as many chips to drive, although each is smaller because each storage location stores only eight bits. As discussed above, each buffer provides two outputs for each input. The duplicate control signal outputs from buffer 3028 are used to drive the additional control inputs in this embodiment, thus reducing loading on each output. The FIG. 18 embodiment includes a clock driver 3030 having nine outputs and an identification memory 3032 like the corresponding devices 3010 and 3012 of FIG. 17.

To maintain a junction temperature, Tj, below 105° C. in the expected system ambient conditions, the following package thermal characteristics are required. A maximum Q JC of 14° C./Watt for the stacked package containing two 256 Mb SDRAM devices including leadframe (case). The SDRAM package theta(JC) should not be greater than 25° C./Watt in still air.

The following Table 2 lists the package types for IC components, chips, used in the NG DIMMs.

TABLE 2

| | | |
|---|---|---|
| | | PACKAGE |
| PART | DESCRIPTION | TYPE |

| | | |
|---|---|---|
| 24C64 | SPD serial | 8-pin TSSOP |
| | EEPROM | |
| 74ALCVH162830 | 18-to-36 Driver | 80-pin TVSOP |
| MPC953 “C” | PLL Clock | 32-lead TQFP |
| | Driver | |
| 4/8/16Mx16 or | PC100 SDRAM | 54pin TSOP |
| 2*32Mx8 SDRAM | | or Stacked package* |

Note:
*For TCP stack the number of pins is 102, 51 for each device.

The NG DIMMs are assembled on multilayer printed circuit boards having eight conductive layers are reserved for power voltage and ground. The remaining six are used for signal routing, with the outer two also used to form mounting locations for surface mounting of memory and other chips. The conductive layers are separated by seven layers of dielectric material 4.4-4.8, FR4/FR5. The layer stackup and descriptions are provided in Table 3.

TABLE 3

| | | | | | Trace | |
|---|---|---|---|---|---|---|
| | | | Trace | Copper | thickness | |
| Layer | Name | width | weight | impedance | ohm +/10% | Dielectric |
| | 1 | Top | 0.008″ | 1 * | 65 | [ ] |
| | 2 | A | 0.004″ | 1 | 55 | [ ] |
| | 3 | GND | n/a | 1 | n/a | [ ] |
| | 4 | B | 0.004″ | 1 | 55 | [ ] |
| | 5 | C | 0.004″ | 1 | 55 | [ ] |
| | 6 | VDD | n/a | 1 | n/a | [ ] |
| | 7 | D | 0.004″ | 1 | 55 | [ ] |
| | 8 | BOT | 0.008″ | 1 * | 65 | [ ] |

Note:
* 1 oz finished

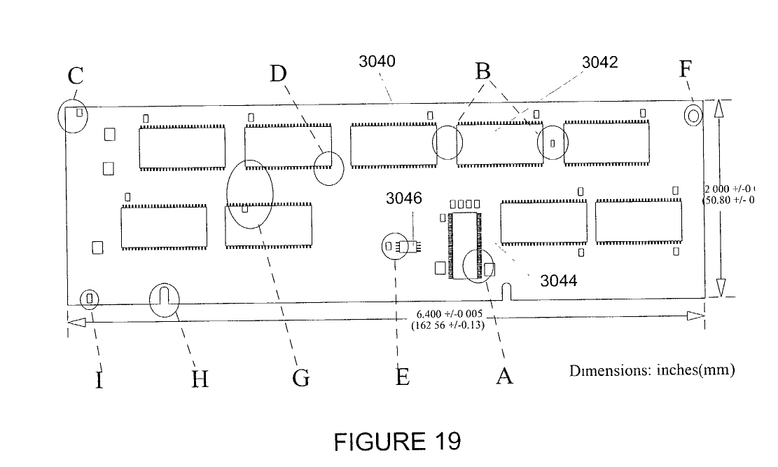

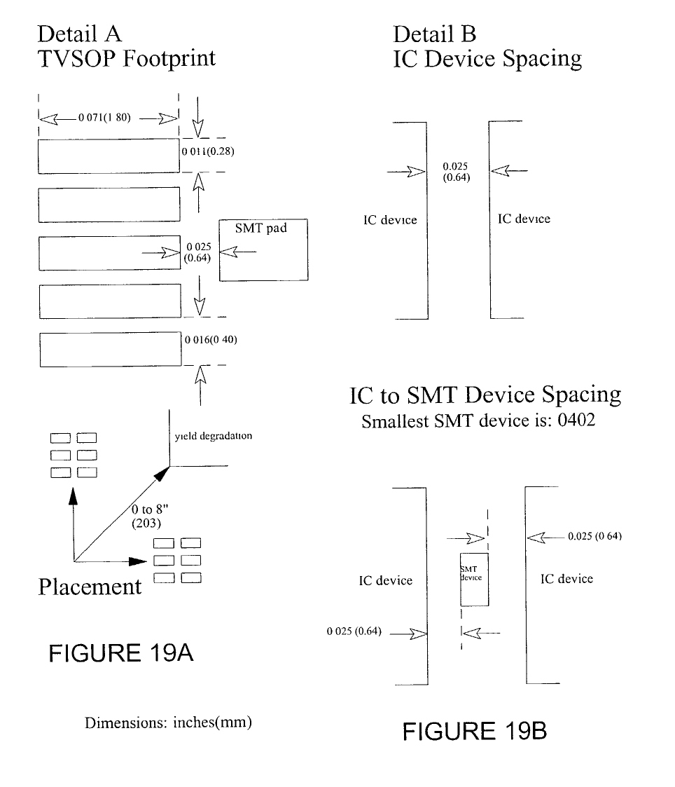

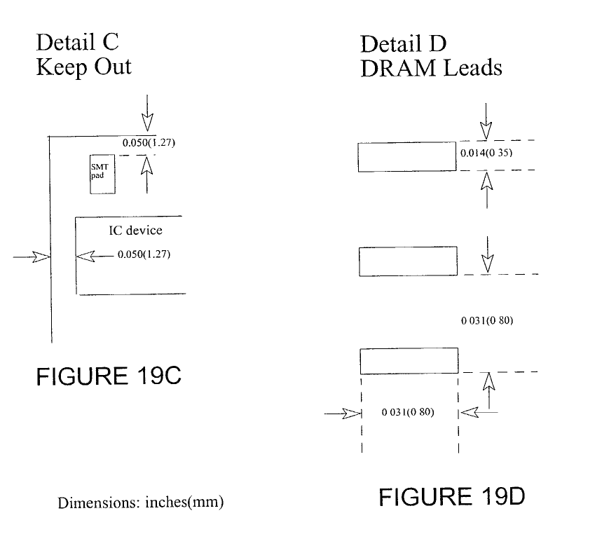

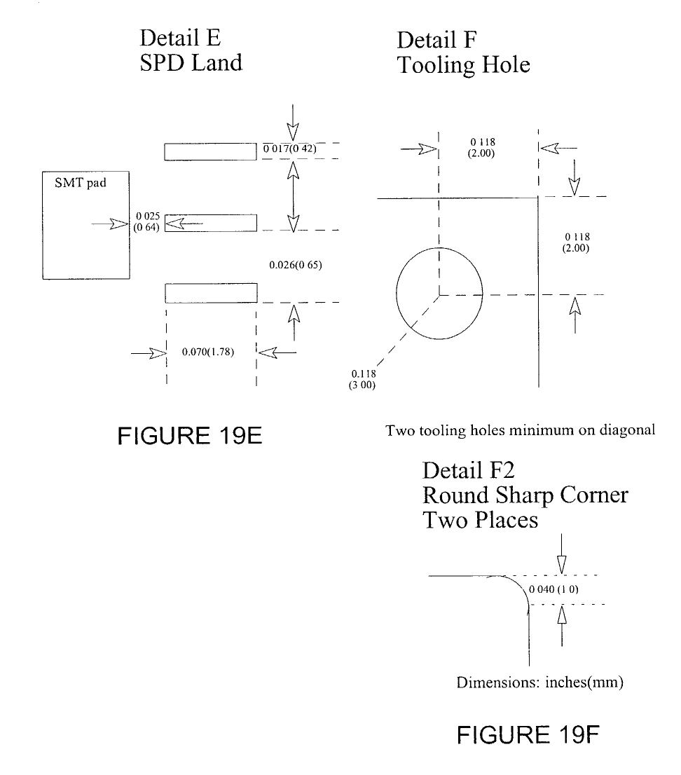

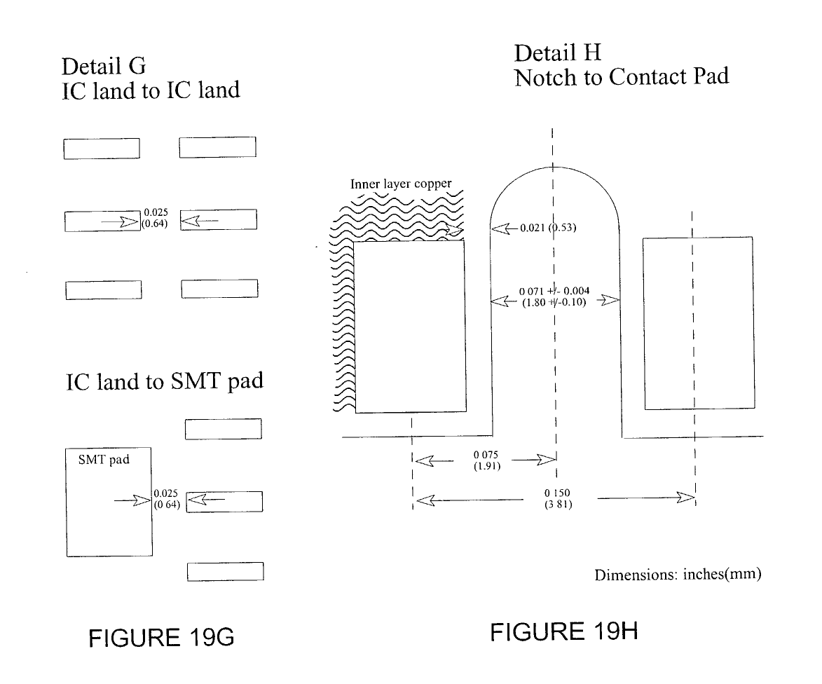

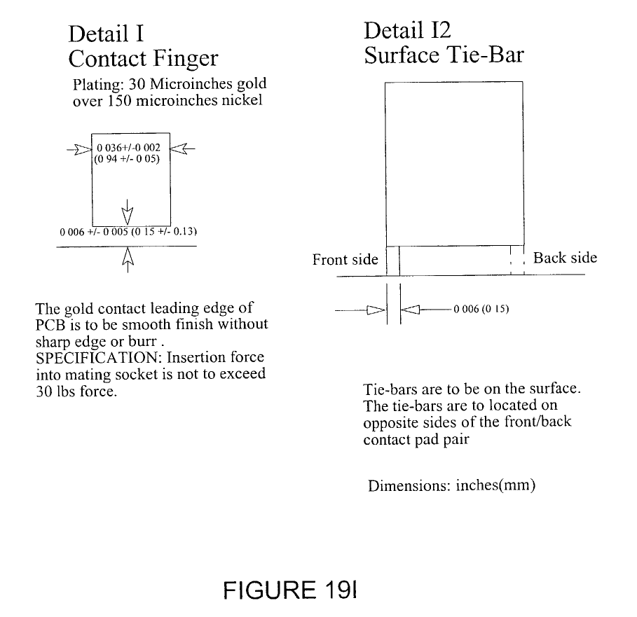

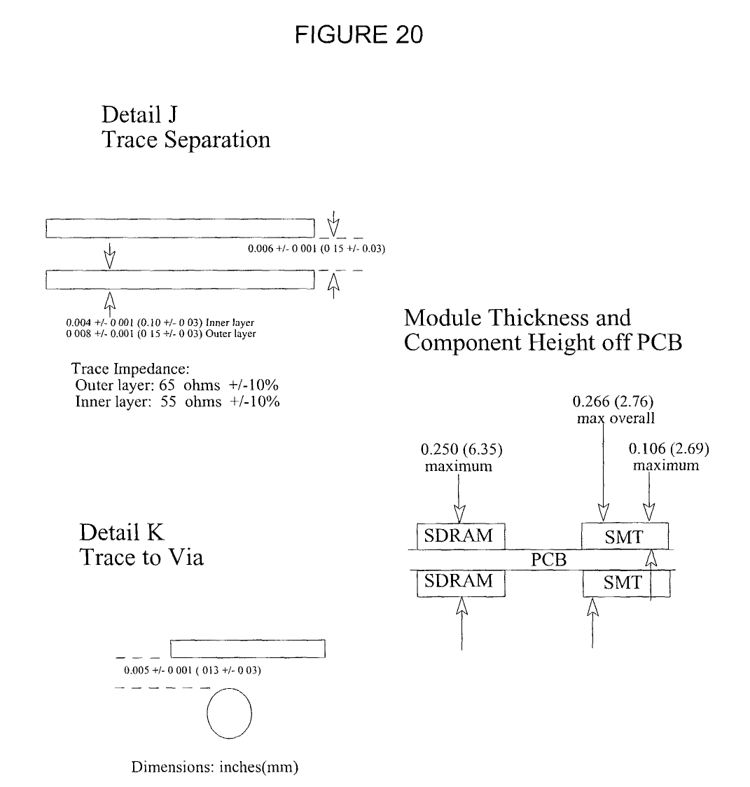

FIG. 19 is a dimensioned drawing of a printed circuit board 3040 on which a memory module is assembled. This drawing shows the placement of one bank of nine memory chips 3042, a buffer 3044 and a clock driver chip 3046. A number of details labeled “A” through “A” are also identified on this figure. FIGS. 19A through 19I are dimensioned drawings showing those details. FIG. 20 provides additional dimensioned details for the printed circuit board of FIG. 19.

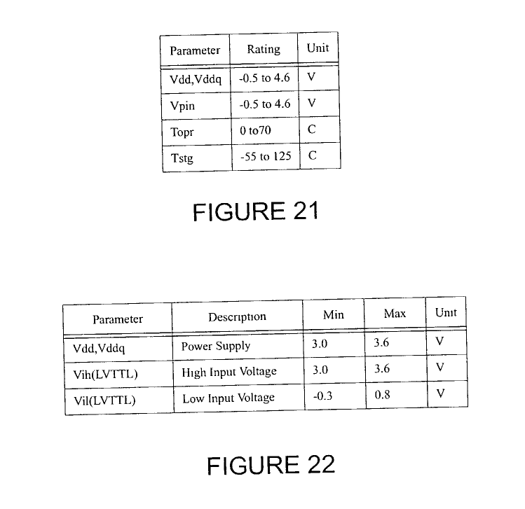

FIG. 21 is a table of electrical absolute maximum ratings for NG DIMMs.

FIG. 22 is a table of recommended operating conditions for NG DIMMs.

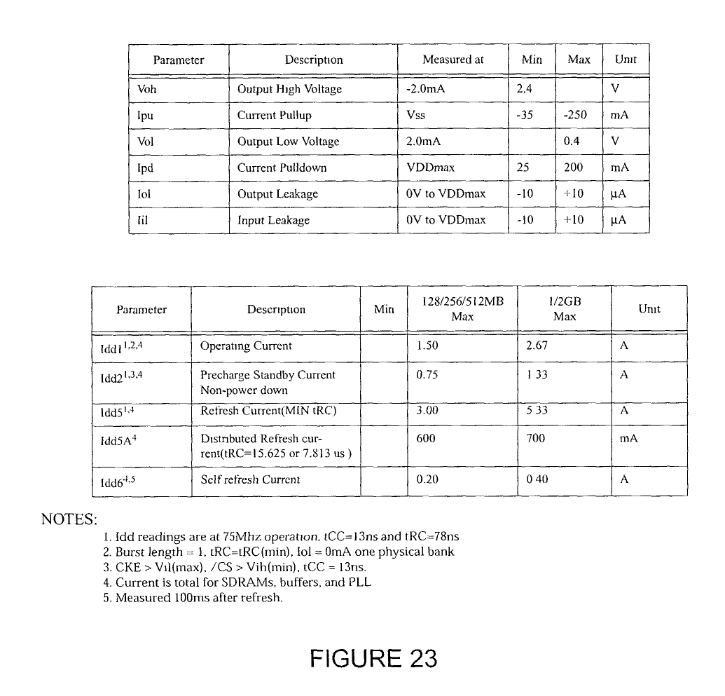

FIG. 23 is a table of DC characteristics for NG DIMMs.

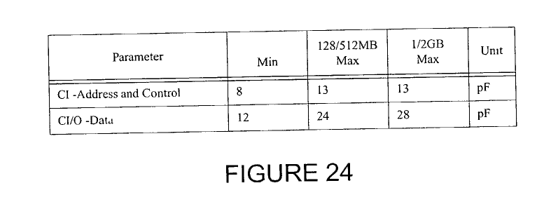

FIG. 24 is a table of capacitance characteristics for NG DIMMs.

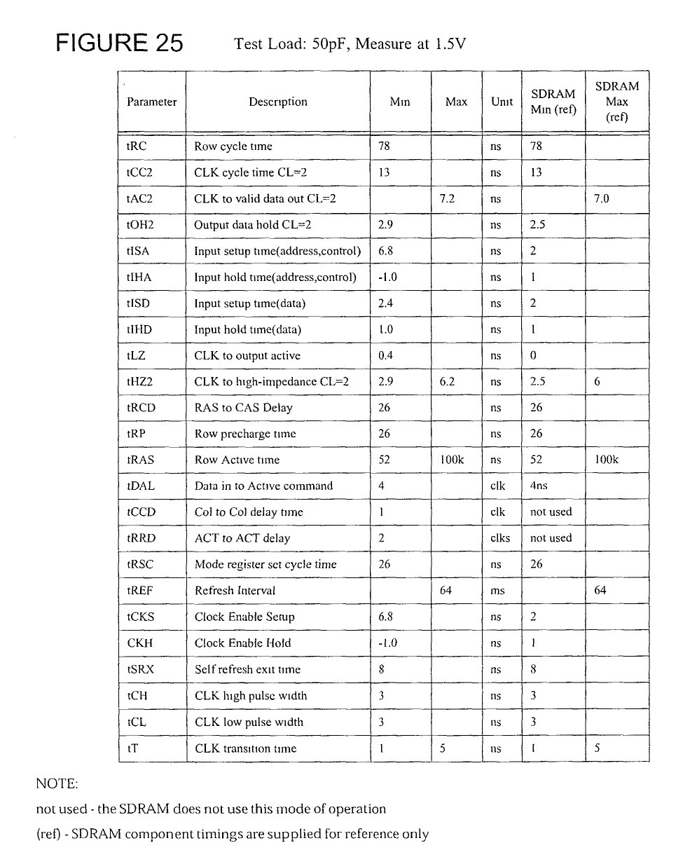

FIG. 25 is a table of AC characteristics for NG DIMMs.

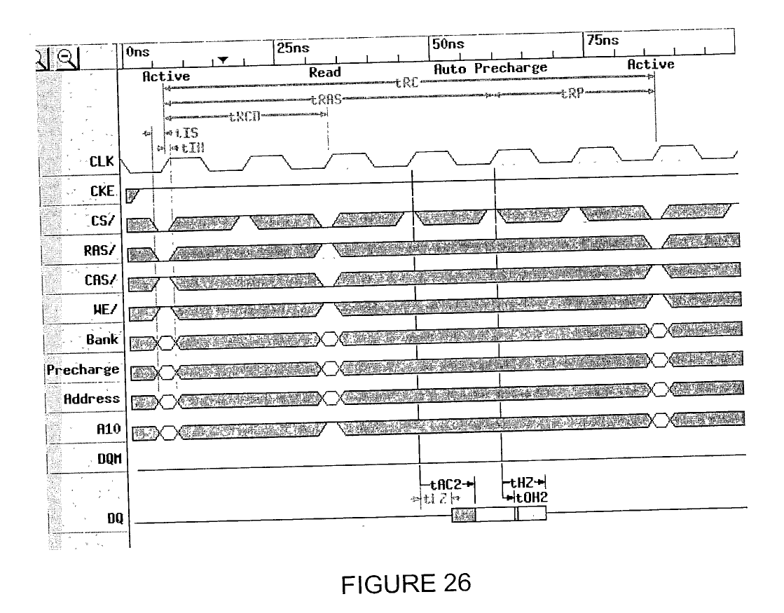

FIG. 26 is a timing diagram for a read transaction for NG DIMMs.

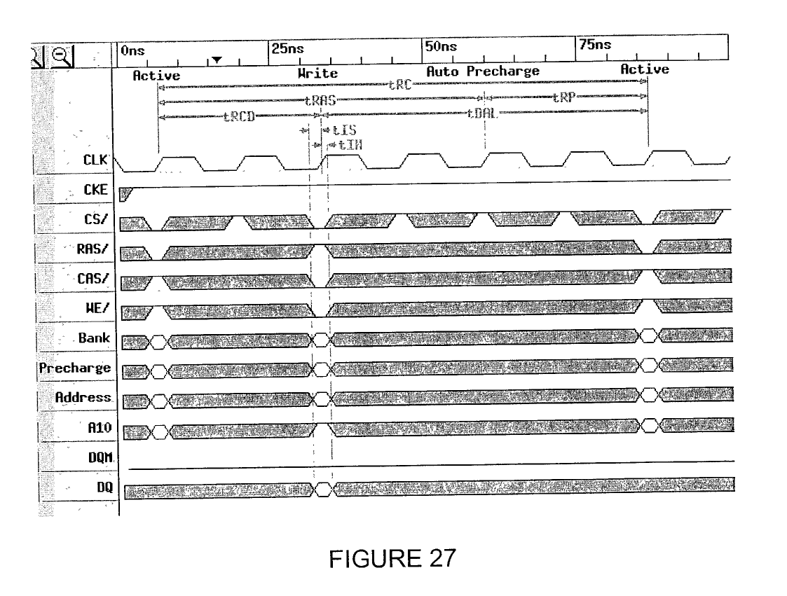

FIG. 27 is a timing diagram for a write transaction for NG DIMMs.

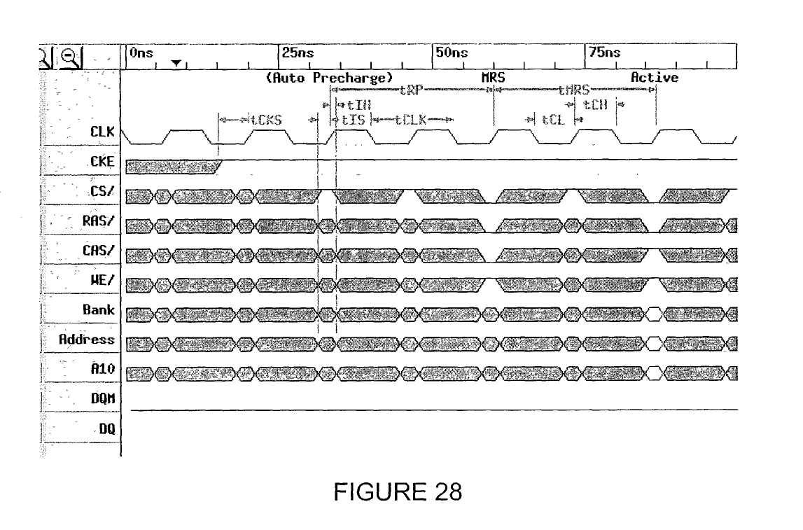

FIG. 28 is a timing diagram for a mode register set cycle for NG DIMMs. This required by SDRAM chips to prepare the chip for a read or write transaction.

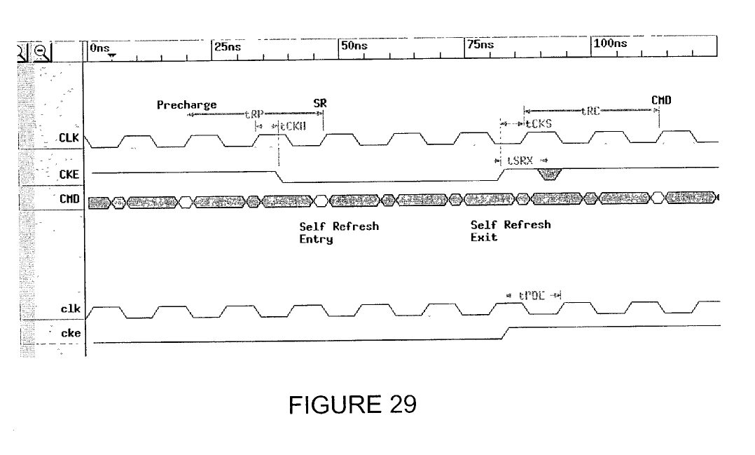

FIG. 29 is a timing diagram for a self-refresh entry and exit cycle for NG DIMMs.

While the invention has been illustrated and described in terms of particular apparatus and methods of use, it is apparent that equivalent parts may be substituted of those shown and other changes can be made within the scope of the invention as defined by the appended claims.

What I claim as my invention is:

1. A memory module, comprising:
a printed circuit board having a first side and a second side, wherein said printed circuit board includes a connector edge adapted for insertion within a socket of said computer system, the connector edge having a plurality of contact pads on said first side and said second side of said printed circuit board;
wherein said plurality of contact pads are configured to convey data signals, power and ground to and from said printed circuit board;
wherein said power and ground contact pads alternate along said connector edge with no more than four adjacent data signal contact pads without intervening power or ground contact pads;
a plurality of memory devices mounted on the printed circuit board for storing data;
a clock driver mounted on the printed circuit board, wherein the clock driver is coupled to each of the plurality of memory devices and is configured to receive a differential clock signal and to produce at least one single-ended clock signal for clocking the plurality of memory devices, and wherein the clock driver includes a phase-locked loop for phase-locking the at least one single-ended clock signal.

2. The memory module as recited in claim 1, wherein the differential clock signal includes a pair of complementary logic signals, and wherein the pair of complementary logic signals are low voltage positive emitter-coupled logic (LVPECL) signals.

3. The memory module as recited in claim 1, wherein the plurality of memory devices comprises synchronous dynamic random access memory (SDRAM) devices.

4. The memory module as recited in claim 1, wherein the memory module is a dual in-line memory module (DIMM).

5. The memory module as recited in claim 1, wherein each of the plurality of memory devices comprises a stacked memory package.

6. The memory module as recited in claim 1, wherein the connector edge comprises 232 contact pads.

7. The memory module as recited in claim 1 further comprising a serial storage unit mounted on the printed circuit board, wherein said serial storage unit stores module identification information.

8. The memory module as recited in claim 1 further comprising a serial storage unit mounted on the printed circuit board, wherein said serial storage unit stores signal line routing information which correlates each of at least some of said contact pads of said connector edge to a corresponding pin of a particular memory device.

9. The memory module as recited in claim 3, wherein the memory module is a dual in-line memory module (DIMM).

10. The memory module as recited in claim 9, wherein the connector edge comprises 232 contact pads.

11. The memory module as recited in claim 10 further comprising a serial storage unit mounted on the printed circuit board, wherein said serial storage unit stores module identification information.

12. The memory module as recited in claim 11 wherein said serial storage unit stores signal line routing information which correlates each of at least some of said contact pads of said connector edge to a corresponding pin of a particular memory device.

13. The memory module as recited in claim 12, wherein each of the plurality of memory devices comprises a stacked memory package.
